(19) United States
(12) Patent Application Publication
(10) Pub. No.: US 2012/0096335 A1
(43) Pub. Date: Apr. 19, 2012

(54) DATA PROCESSING METHOD AND SEMICONDUCTOR INTEGRATED CIRCUIT

(75) Inventors: Tsukasa TAKAHASHI, Osaka (JP); Tomohisa Sezaki, Kyoto (JP); Nobuhiro Tsuboi, Osaka (JP); Yoshiteru Mino, Osaka (JP)

(73) Assignee: Panasonic Corporation, Osaka (JP)

(21) Appl. No.: 13/336,647

(22) Filed: Dec. 23, 2011

Related U.S. Application Data
(63) Continuation of application No. PCT/JP2009/006753, filed on Dec. 10, 2009.

(30) Foreign Application Priority Data
Jun. 30, 2009 (JP) 2009-155170

(51) Int. Cl. G06F 12/02; G06F 11/10; H03M 13/05

(52) U.S. Cl. 714/773; 711/103; 711/E12.008; 714/E11.035

(57) ABSTRACT

A read process is performed on an ith designated block storing an ith divided data string. If the ith divided data string is not normally read, the read process is sequentially executed on ith ordinary blocks each storing the ith divided data string, where the ith ordinary blocks are included in ordinary block groups, respectively. When the ith divided data string is normally read, it is determined whether or not reading p divided data strings has been completed. If it is determined that the reading the p divided data strings has not been completed, the read process is performed on an (i+1)th designated block storing an (i+1)th divided data string following the ith divided data string.

### CROSS-REFERENCE TO RELATED APPLICATION

This is a continuation of PCT International Application PCT/JP2009/006753 filed on Dec. 10, 2009, which claims priority to Japanese Patent Application No. 2009-155170 filed on Jun. 30, 2009. The disclosures of these applications including the specifications, the drawings, and the claims are hereby incorporated by reference in their entirety.

### BACKGROUND

The technology disclosed in this specification relates to methods for sequentially processing data strings in flash memories on a block-by-block basis, and to semiconductor integrated circuits, specifically to improvement of data read reliability (the probability that normal data can be read).

In recent years, system LSIs including a large number of functions integrated on one chip are used in various electronic devices. Moreover, non-volatile memories which store various processing programs such as a boot program and data are provided inside or outside the system LSIs. As such non-volatile memories, flash memories which allow stored data to be rewritten with new data have been widely used. Flash memories used to store boot programs are generally NOR type flash memories. However, recently, there has been an increase in opportunities to use NAND type flash memories whose price per bit is low. It has been known that defective blocks randomly develop in the NAND type flash memories during the process of fabricating and using the NAND type flash memories. Thus, when boot programs are stored in the NAND type flash memories, it is necessary to check that blocks in which the boot programs are stored are not defective blocks in order to guarantee that the boot programs are normally stored.

Japanese Patent Publication No. 2007-304781 (Patent Document 1) discloses a technique for avoiding execution of boot programs stored in defective blocks. In Patent Document 1, identical boot programs (program data) are stored in advance in a plurality of blocks of a NAND type flash memory. It is determined whether or not read program data is defective. If it is determined that the read program data is defective, program data corresponding to the program data which has been determined to be defective is read from a block different from the block storing the program data which has been determined to be defective.

### SUMMARY

Some blocks included in a NAND type flash memory are guaranteed to be normal blocks (blocks from which data can be normally read) by a manufacturer of the NAND type flash memory before shipment (blocks guaranteed to be normal blocks by a manufacturer before shipment are hereinafter referred to as “designated blocks”). However, in the semiconductor device of Patent Document 1, a designated block is not always preferentially selected as a target of a read process, and another block with a lower degree of reliability than the designated block may be continuously selected as the target of the read process. Thus, it has been difficult to increase data read reliability (the probability that normal data can be read). Note that a similar problem also arises when the NAND type flash memory stores a data string other than the boot program.

Thus, it is an objective of the technique disclosed in this specification to provide a method for reading data with a high degree of data read reliability and a semiconductor integrated circuit.

A data processing method according to an aspect of the invention is a data processing method for sequentially processing a data string stored in a flash memory on a block-by-block basis, wherein the flash memory includes p designated blocks, where p≧2, and ordinary block groups, each of the ordinary block groups includes p ordinary blocks, p divided data strings obtained by dividing the data string into p strings are stored in the p designated blocks, respectively, the p divided data strings stored in the p designated blocks are respectively copied to the p ordinary blocks included in each of the ordinary block groups, and reliability of the designated blocks is higher than reliability of the ordinary blocks, the data processing method including: (a) executing a read process on an ith designated block storing an ith divided data string, where 1≦i≦n; (b) sequentially executing the read process on ith ordinary blocks each of which stores the ith divided data string and which are respectively included in the ordinary block groups if the ith divided data string is not normally read in the step (a); (c) determining whether or not reading the p divided data strings has been completed if the ith divided data string is normally read in any one of the step (a) or (b); and (d) executing the read process on an (i+1)th designated block storing an (i+1)th divided data string following the ith divided data string if it is determined in the step (c) that the reading the p divided data strings has not been completed. In the data processing method, a designated block having a higher degree of reliability than an ordinary block is preferentially selected as a block on which a read process is performed, so that it is possible to increase data read reliability (the probability that a normal divided data string can be read).

Note that each of the p designated blocks and the p ordinary blocks included in each of the ordinary block groups may store a defective block mark to determine whether the block is a defective block or a normal block, and the read process may include (e1) reading the defective block mark stored in a target block on which the read process is performed, and determining, based on the defective block mark, whether the target block is a defective block or a normal block, (e2) determining that the divided data string is not normally readable from the target block if it is determined in the step (e1) that the target block is a defective block, and (e3) reading the divided data string stored in the target block if it is determined in the step (e1) that the target block is a normal block. With this method, it is possible to avoid not only a defective page but also pages which is likely to be defective pages, so that it is possible to increase the data read reliability compared to the case where normality/defect management is performed on a page-by-page basis.

Moreover, each of the p designated blocks and the p ordinary blocks included in each of the ordinary block groups may store an error correcting code used to detect and correct an error in the divided data string stored therein, in the step (e3), the divided data string stored in the target block is read, and the error correcting code stored in the target block is read, and the read process may further include (e4) detecting and correcting an error in the divided data string read in the step (e3) based on the error correcting code read in the step (e3).

The data processing method may further include (f) storing, in a non-volatile memory, history information indicating from which blocks the p divided data strings have been normally read if it is determined in the step (c) that the reading the p divided data strings has been completed. In the data processing method, it is possible to avoid accessing an unreadable block (block from which divided data string cannot be normally read) by referring to the history information stored in the non-volatile memory in next data processing.

The data processing method may further include: (g) determining whether or not the history information has been stored in the non-volatile memory; (h) executing, based on the history information, the read process on any one of the ith designated block or the ith ordinary blocks each storing the ith divided data string if it is determined in the step (g) that the history information has been stored in the non-volatile memory; (i) determining whether or not the history information is stored in the non-volatile memory if it is determined in the step (c) that the reading the p divided data strings has not been completed; and (j) executing, based on the history information, the read process on any one of the (i+1)th designated block or (i+1)th ordinary blocks each storing the (i+1)th divided data string if it is determined in the step (i) that the history information has been stored in the non-volatile memory, wherein the step (a) is performed when it is determined in the step (g) that the history information has not been stored in the non-volatile memory, the step (b) is performed when the ith divided data string is not normally read in any one of the step (a) or (h), the step (c) is performed when the ith divided data string is normally read in any one of the step (a), (b), or (h), and the step (d) is performed when it is determined in the step (i) that the history information has not been stored in the non-volatile memory. In the data processing method, it is possible to avoid accessing an unreadable block based on the history information.

Alternatively, the data processing method may further include (k) detecting, for each of the p divided data strings, among the designated block and the ordinary blocks each storing the divided data string, the number of blocks from which the divided data string is not normally read as the number of unreadable blocks; (l) determining, for each of the divided data strings, whether or not the number of unreadable blocks detected in the step (k) is larger than a preset threshold value; and (m) copying the divided data string, for which it is determined in the step (l) that the number of unreadable block is larger than the threshold value, to an unused block. In the data processing method, when a copying process is performed based on the number of unreadable blocks of each of the divided data strings, it is possible to avoid the situation in which a data string cannot be accurately reconstructed.

Note that the data string may be a boot program to activate a CPU, and the data processing method may further include: (n) transferring the ith divided data string normally read in any one of the step (a) or (b) to a RAM, and (o) allowing the CPU to execute the p divided data strings transferred to the RAM as the boot program if it is determined in the step (c) that the reading the p divided data strings has been completed. In the data processing method, the probability that a normal divided program can be read increases, so that the boot program can be accurately reconstructed, which can reduce faulty operation of the semiconductor device caused by an incorrect boot program performed by the CPU.

A semiconductor integrated circuit according to another aspect of the present invention is A semiconductor integrated circuit for sequentially processing a data string stored in a flash memory on a block-by-block basis, the semiconductor integrated circuit including: a CPU; and a RAM, wherein the flash memory includes p designated blocks, where p≧2, and ordinary block groups, each of the ordinary block groups includes p ordinary blocks, p divided data strings obtained by dividing the data string into p strings are stored in the p designated blocks, respectively, the p divided data strings stored in the p designated blocks are respectively copied to the p ordinary blocks included in each of the ordinary block groups, reliability of the designated blocks is higher than reliability of the ordinary blocks, the CPU executes a read process on an ith designated block storing an ith divided data string, where 1≦i≦n, the CPU sequentially executes the read process on ith ordinary blocks each of which stores the ith divided data string and which are respectively included in the ordinary block groups if the ith divided data string is not normally read from the ith designated block, the CPU transfers the ith divided data string normally read from any one of the ith designated block or the ith ordinary blocks to the RAM, the CPU determines whether or not reading the p divided data strings has been completed if the ith divided data string is normally read from any one of the ith designated block or the ith ordinary blocks, and the CPU executes the read process on an (i+1)th designated block storing an (i+1)th divided data string following the ith divided data string if the CPU determines that the reading the p divided data strings has not been completed. In the semiconductor integrated circuit, a designated block having a high degree of reliability than an ordinary block is preferentially selected as a block on which a read process is performed, so that it is possible to increase data read reliability (the probability that a normal divided data string can be read).

Note that the data string may be a boot program, and the CPU may execute the p divided data strings transferred to the RAM as the boot program if the CPU determines that the reading the p divided data strings has been completed.

Moreover, the semiconductor integrated circuit may further include a non-volatile memory configured to store a start-up program which allows the CPU to sequentially process the data string stored in the flash memory on a block-by-block basis, wherein the CPU may operate based on the start-up program stored in the non-volatile memory.

### BRIEF DESCRIPTION OF THE DRAWINGS

FIG. 1 is a view illustrating an example configuration of a semiconductor device of a first embodiment.

FIG. 2 is a view illustrating an example structure of a NAND type flash memory of FIG. 1.

FIG. 3 is a view illustrating a boot program stored in the NAND type flash memory of FIG. 1.

FIG. 4 is a view illustrating a start-up process of the semiconductor device of FIG. 1.

FIG. 5 is a view illustrating a boot program reading process.

FIG. 6 is a view illustrating an example configuration of a semiconductor device of a second embodiment.

FIG. 7 is a view illustrating unreadable blocks in a NAND type flash memory of FIG. 6.

FIG. 8 is a view illustrating boot history information.

FIG. 9 is a view illustrating a start-up process of the semiconductor device of FIG.

FIG. 10 is a view illustrating the start-up process of the semiconductor device of FIG. 6.

FIG. 11 is a view illustrating an example configuration of a semiconductor device of a third embodiment.

FIG. 12 is a view illustrating a copying process in the semiconductor device of FIG. 11.

FIG. 13 is a view illustrating a specific example of the copying process in the semiconductor device of FIG. 11.

FIG. 14 is a view illustrating another specific example of the copying process in the semiconductor device of FIG. 11.

### DETAILED DESCRIPTION

Embodiments will be described in detail below with reference to the drawings. In the drawings, like reference characters are used to designate identical or equivalent elements, and explanation thereof is not repeated.

### First Embodiment

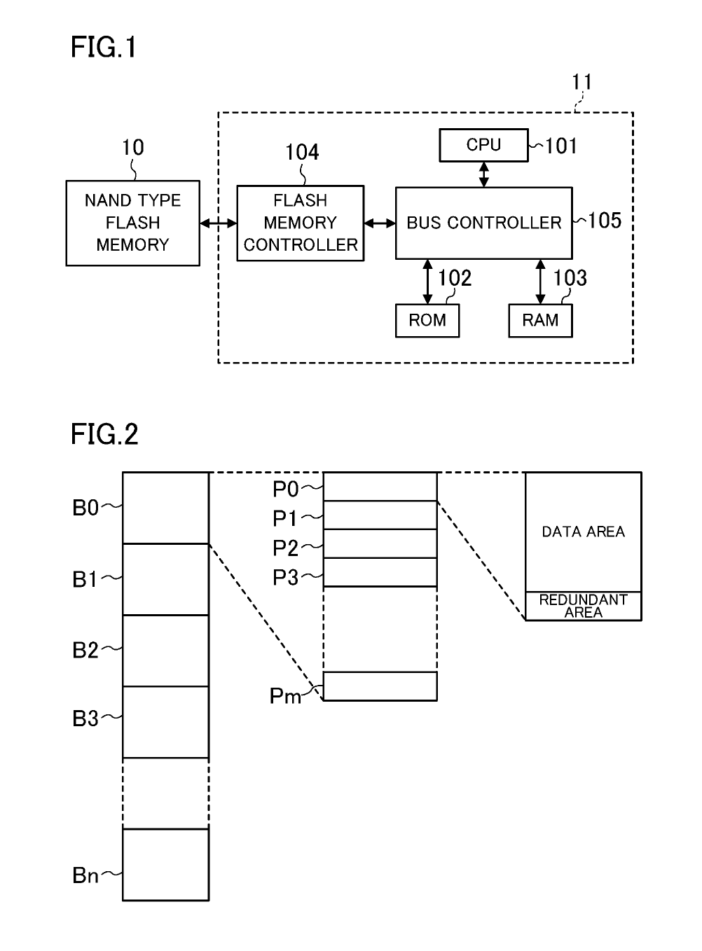

FIG. 1 illustrates an example configuration of a semiconductor device according to a first embodiment. The semiconductor device includes a NAND type flash memory 10, and a system LSI 11 (semiconductor integrated circuit). The NAND type flash memory 10 is provided outside the system LSI 11. The system LSI 11 includes a variety of circuits integrated on a single semiconductor chip.

[NAND Type Flash Memory]

The NAND type flash memory 10 stores a variety of processing programs and data including a boot program to activate the semiconductor device.

As illustrated in FIG. 2, the NAND type flash memory 10 includes a plurality of blocks B0, B1, . . . , Bn (n≧2). Each of the blocks B0, B1, . . . , Bn includes a plurality of pages P0, P1, . . . , Pm (m≧2). Unique block numbers (0, 1, . . . , n) are assigned to the blocks B0, B1, . . . , Bn, respectively. Unique page numbers (0, 1, . . . , m) are assigned to the pages P0, P1, . . . , Pm, respectively. In accessing the NAND type flash memory 10, the block number of a block which is to be accessed is first specified, and the page number of a page which is to be accessed is further specified. In this way, data is read and/or written on a page-by-page basis.

Moreover, each of the pages P0, P1, . . . , Pm includes a data area and a redundant area. The redundant area stores management information such as an error correcting code (ECC). The error correcting code is used to detect or correct an error in data stored in the data area. Moreover, the redundant area of the first page P0 stores a defective block mark. The defective block mark is information to determine whether the block including the page P0 is a defective block (block from which data cannot be normally read) or a normal block (block from which data can be normally read). With reference to the value of the defective block mark, whether the block is a defective block or a normal block can be determined.

Moreover, some of the blocks B0, B1, . . . , Bn included in the NAND type flash memory 10 are guaranteed to be normal blocks by a manufacturer of the NAND type flash memory before shipment. In the following description, among the blocks B0, B1, . . . , Bn, some blocks which are guaranteed to be normal blocks by the manufacturer before shipment are referred to as “designated blocks,” and other blocks are referred to as “ordinary blocks.” That is, the reliability (the probability that normal data can be read) of the designated blocks is higher than that of the ordinary blocks.

[Storing Boot Program]

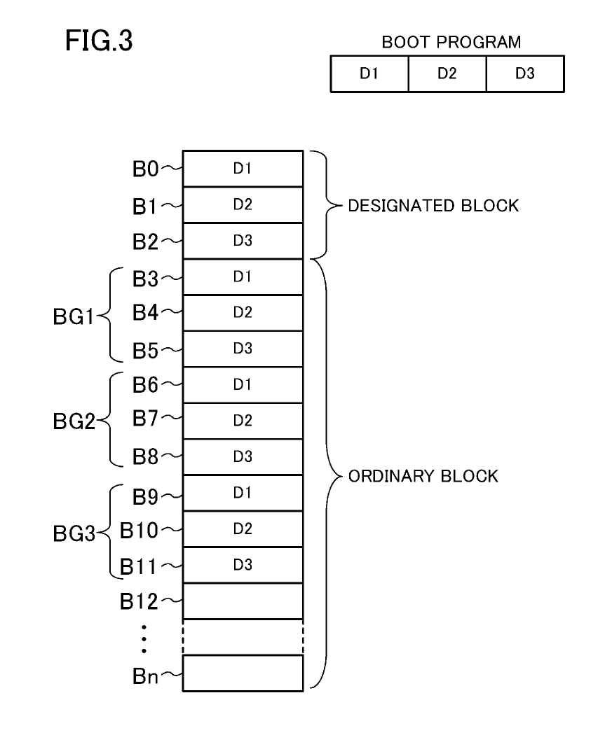

Next, with reference to FIG. 3, storing the boot program in the NAND type flash memory 10 illustrated in FIG. 1 will be described. Here, three blocks B0, B1, B2 are “designated blocks,” and other blocks B3, B4, . . . , Bn are “ordinary blocks.”

The three designated blocks B0, B1, B2 store three divided programs D1, D2, D3, respectively. The three divided programs D1, D2, D3 are obtained by dividing one boot program into three programs. The divided programs D1, D2, D3 stored in the designated blocks B0, B1, B2 are copied to ordinary blocks B3, B4, B5, respectively. Likewise, the divided programs D1, D2, D3 stored in the designated blocks B0, B1, B2 are copied to the ordinary blocks B6, B7, B8, respectively, and to the ordinary blocks B9, B10, B11, respectively. Note that the ordinary blocks B12, . . . , Bn are unused blocks in which the divided programs D1, D2, D3 are not stored.

Here, given that the ordinary blocks B3, B4, B5 are included in an ordinary block group BG1, the ordinary blocks B6, B7, B8 are included in an ordinary block group BG2, and the ordinary blocks B9, B10, B11 are included in an ordinary block group BG3, each of first ordinary blocks (the ordinary blocks B3, B6, B9) respectively included in the ordinary block groups BG1, BG2, BG3 stores the first divided program D1, each of second ordinary blocks (the ordinary blocks B4, B7, B10) respectively included in the ordinary block groups BG1, BG2, BG3 stores the second divided program D2, and each of third ordinary blocks (the ordinary blocks B5, B8, B11) respectively included in the ordinary block groups BG1, BG2, BG3 stores the third divided program D3.

[System LSI]

Referring back to FIG. 1, the system LSI 11 includes a CPU 101, a ROM 102, a RAM 103, a flash memory controller 104, and a bus controller 105.

The CPU 101 is connected to the ROM 102, the RAM 103, and the flash memory controller 104 via the bus controller 105. The ROM 102 is a non-volatile memory which allows data to be accessed randomly, and stores a start-up program. The RAM 103 is a non-volatile memory which allows data to be accessed randomly, and is a memory to which the boot program stored in the NAND type flash memory 10 is transferred (a memory configured to store the boot program transferred from the NAND type flash memory 10).

The flash memory controller 104 is a circuit configured to control a read process of the NAND type flash memory 10. In response to the specification of a block number and a page number of the NAND type flash memory 10 by the CPU 101, the flash memory controller 104 reads a divided program from the NAND type flash memory 10 on a page-by-page basis. The flash memory controller 104 also reads the error correcting code stored in the page, and based on the error correcting code, the flash memory controller 104 performs error detection and error correction on one page's worth of the divided program.

The bus controller 105 connects the CPU 101, the ROM 102, the RAM 103, and the flash memory controller 104 to each other by buses, and controls access of the CPU 101 to the ROM 102, RAM 103, and flash memory controller 104.

After canceling a reset of the system LSI 11, the CPU 101 accesses the ROM 102, and executes the start-up program stored in the ROM 102. The start-up program is a program which allows the CPU 101 to sequentially process, on a block-by-block basis, the boot program stored in the NAND type flash memory 10 to transfer the boot program stored in the NAND type flash memory 10 to the RAM 103, and then to execute the boot program stored in the RAM 103.

[Operation]

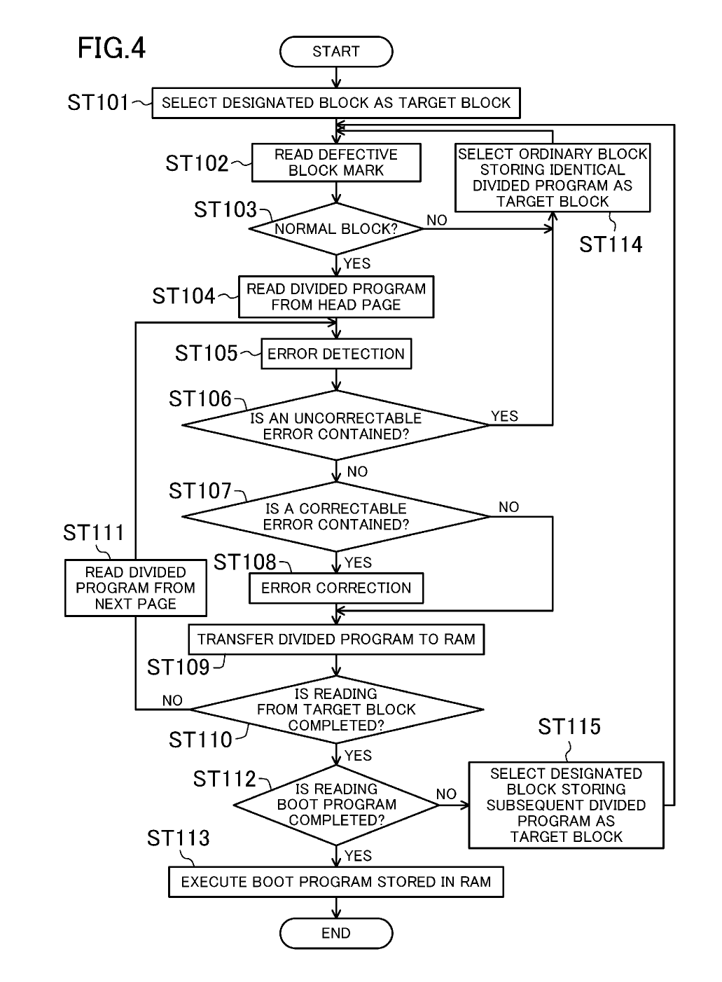

Next, with reference to FIG. 4, a start-up process of the semiconductor device illustrated in FIG. 1 will be described. After the reset of the system LSI 11 is canceled, the CPU 101 executes the following operation according to the start-up program stored in the ROM 102.

<<Step ST101>>

First, the CPU 101 specifies the block number “0” of the first designated block B0 among the blocks in the NAND type flash memory 10, and the page number “0” of the first page P0 included in the designated block B0. The first designated block B0 is thus selected as a target block (a block on which a read process is performed).

<<Step ST102>>

Next, based on the block number and the page number specified by the CPU 101, the flash memory controller 104 reads the defective block mark from the redundant area of the first page P0 included in the target block.

<<Step ST103>>

Then, the CPU 101 determines whether the target block is a normal block or a defective block based on the value of the defective block mark read by the flash memory controller 104. If the target block is a normal block, the process proceeds to step ST104. On the other hand, if the target block is a defective block, the CPU 101 determines that the divided program is not normally readable from the target block, and the process proceeds to step ST114.

<<Step ST104>>

Next, in response to control by the CPU 101, the flash memory controller 104 reads a portion of the divided program from the first page P0 (i.e., head page) of the target block, and reads the error correcting code from the redundant area of the first page P0. In this way, one page's worth of the divided program is read.

<<Step ST105>>

Next, based on the error correcting code, the flash memory controller 104 performs error detection on the one page's worth of the divided program.

<<Step ST106>>

Next, the flash memory controller 104 determines whether or not the one page's worth of the divided program includes an uncorrectable error. If the one page's worth of the divided program does not include an uncorrectable error, the process proceeds to step ST107. On the other hand, if the one page's worth of the divided program includes an uncorrectable error, the CPU 101 determines that the divided program is not normally readable from the target block, and the process proceeds to step ST114.

<<Step ST107>>

Next, the flash memory controller 104 determines whether or not the one page's worth of the divided program includes a correctable error. If the one page's worth of the divided program includes a correctable error, the process proceeds to step ST108. On the other hand, if the one page's worth of the divided program does not include a correctable error, the process proceeds to step ST109.

<<Step ST108>>

Next, the flash memory controller 104 performs error correction on the correctable error in the one page's worth of the divided program.

<<Step ST109>>

Next, in response to the control by the CPU 101, the flash memory controller 104 transfers the one page's worth of the divided program to the RAM 103.

<<Step ST110>>

Next, the CPU 101 determines whether or not reading from the target block has been completed (whether or not one block's worth of the divided program has been read from the target block). If the reading from the target block has not been completed, the process proceeds to step ST111. If the reading from the target block has been completed, the process proceeds to step ST112.

<<Step ST111>>

Next, the CPU 101 specifies the page number of a next page in the target block. In response to the control by the CPU 101, the flash memory controller 104 reads a portion of the divided program from the next page in the target block. Next, the process proceeds to step ST105. In this way, the divided program is read from the target block, and is processed on a page-by-page basis.

<<Step ST112>>

By contrast, if it is determined in step ST110 that the reading from the target block has been completed, the CPU 101 determines whether or not reading the boot program has been completed (whether or not reading the three divided programs D1, D2, D3 forming one boot program has been completed). If the reading the boot program has been completed, the process proceeds to step ST113. If the reading the boot program has not been completed, the process proceeds to step ST115.

<<Step ST113>>

Next, based on the boot program stored in the RAM 103 (boot program reconstructed from the divided programs D1, D2, D3), the CPU 101 activates the semiconductor device.

<<Step ST114>>

On the other hand, if it is determined in step ST103 or in ST106 that the divided program is not normally readable from the target block (if it is determined in step ST103 that the target block is a defective block, or if it is determined in step ST106 that the divided program of the target block includes an uncorrectable error), the CPU 101 selects an ordinary block storing a divided program identical with the divided program stored in the current target block as a next target block. Next, the process proceeds to step ST102. For example, in the case of FIG. 3, when the CPU 101 selects the designated block B0 as a current target block, the CPU 101 selects the ordinary block B3 as a next target block, and when the CPU 101 selects the ordinary block B3 as a current target block, the CPU 101 selects the ordinary block B6 as a next target block. Thus, the ordinary blocks B3, B6, B9 which store identical programs are each selected as a target block in the order of the ordinary block groups BG1, BG2, BG3. Note that if the divided program cannot be normally read from any of the ordinary blocks each storing the divided program identical with the divided program stored in the current target block, the CPU 101 ends the read process performed on the NAND type flash memory 10. In this case, the semiconductor device is not activated. For example, in the case of FIG. 3, if the divided program D1 cannot be normally read from the designated block B0, and the divided program cannot be normally read from any of the ordinary blocks B3, B6, B9, the CPU 101 ends the read process performed on the NAND type flash memory 10.

<<Step ST115>>

If it is determined in step ST112 that the reading the boot program has not been completed, the CPU 101 selects a designated block storing a subsequent divided program (a divided program following the divided program read from the current target block) as a next target block. Next, the process proceeds to step ST102. For example, in the case of FIG. 3, when the CPU 101 selects the designated block B0 as a current target block, the CPU 101 selects the designated block B1 as a next target block, and when the CPU 101 selects the ordinary block B4 as a current target block, the CPU 101 selects the designated block B2 as a next target block.

[Boot Program Reading Process]

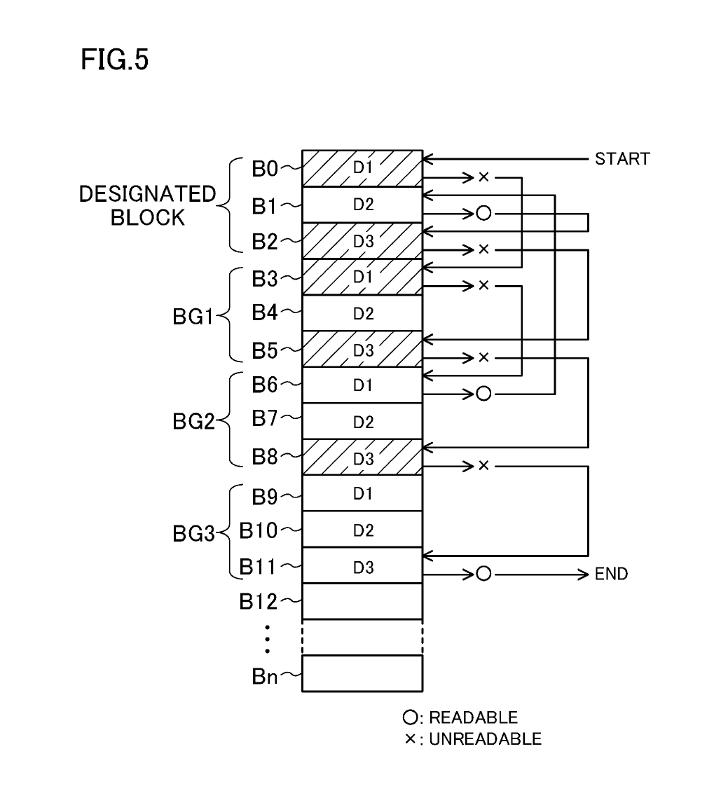

Next, with reference to FIG. 5, a boot program reading process will be described. Here, the designated blocks B0, B2, and the ordinary blocks B3, B5, B8 are unreadable blocks (blocks from which the divided programs cannot be normally read).

First, the CPU 101 selects the first designated block B0 storing the first divided program D1 as a target block, and performs the read process (ST102-ST111) on the designated block B0.

Next, the CPU 101 selects the ordinary block B3 storing the divided program D1 as a next target block since the divided program D1 cannot be normally read from the designated block B0. Then, the CPU 101 performs the read process on the ordinary block B3. Next, the CPU 101 selects the ordinary block B6 storing the divided program D1 as a next target block since the divided program D1 also cannot be normally read from the designated block B3. Then, the CPU 101 performs the read process on the ordinary block B6. Thus, when the first divided program D1 cannot be normally read from the first designated block B0, the CPU 101 performs the read process on the first ordinary blocks B3, B6, B9 included in the ordinary block groups BG1, BG2, BG3, respectively in the order of the ordinary block groups BG1, BG2, BG3.

Next, the CPU 101 normally reads the divided program D1 from the ordinary block B6, and determines whether or not the reading the three divided programs D1, D2, D3 has been completed. Here, since the reading the divided programs D2, D3 has not been completed, the CPU 101 selects the second designated block B1 storing the second divided program D2 following the first divided program D1 as a next target block. Then, the CPU 101 performs the read process on the designated block B1.

Next, the CPU 101 normally reads the divided program D2 from the designated block B1, and determines whether or not the reading the divided programs D1, D2, D3 has been completed. Here, since reading the divided program D3 has not been completed, the CPU 101 selects the third designated block B2 storing the third divided program D3 following the second divided program D2 as a next target block. Then, the CPU 101 performs the read process on the designated block B2.

Next, the CPU 101 selects the ordinary block B5 storing the divided program D3 (a third ordinary block included in the ordinary block group BG1) as a next target block since the divided program D3 cannot be normally read from the designated block B2. Then, the CPU 101 performs the read process on the ordinary block B5. Next, the CPU 101 selects the ordinary block B11 (a third ordinary block included in the ordinary block group BG3) as a target block since the divided program cannot be normally read from any of the ordinary blocks B5, B8. Then, the CPU 101 performs the read process on the ordinary block B11.

Next, the CPU 101 normally reads the divided program D3 from the ordinary block B11, and determines whether or not the reading the divided programs D1, D2, D3 has been completed. Here, the reading the divided programs D1, D2, D3 has been completed, and thus the CPU 101 activates the semiconductor device based on the boot program (the divided programs D1, D2, D3) transferred to the RAM 103.

As described above, when a designated block, which has a higher degree of reliability than ordinary blocks, is preferentially selected as a target on which the read process is performed, it is possible to increase the data read reliability (the probability that a normal divided program can be read). Moreover, when the probability that a normal divided program can be read is increased, the boot program can be accurately reconstructed, so that it is possible to reduce faulty operation of the semiconductor device caused by an incorrect boot program executed by the CPU 101. Thus, the semiconductor device can be stably activated.

In the semiconductor device of Patent Document 1, since defective data is avoided on a page-by-page basis but not on a block-by-block basis of the NAND type flash memory, a block including a defective page (a page from which data cannot be normally read) is not managed as a defective block. For example, even if a block includes a defective page, the block is not managed as a defective block, but is managed based on the understanding that data can be normally read from other pages included in the block. Thus, managing the block including the defective page as a “defective block” to avoid using the block including the defective page is not possible. Moreover, when a page is a defective page, it is highly likely that other pages located near the defective page are also defective pages. That is, when a block includes a defective page, it is highly likely that other pages included in the block are defective pages. In the semiconductor device illustrated in FIG. 1, normality/defect management is performed on a block-by-block basis, so that it is possible to avoid defective pages and pages which are highly likely to be defective pages. Thus, data read reliability can be increased compared to the case where normality/defect management is performed on a page-by-page basis.

### Second Embodiment

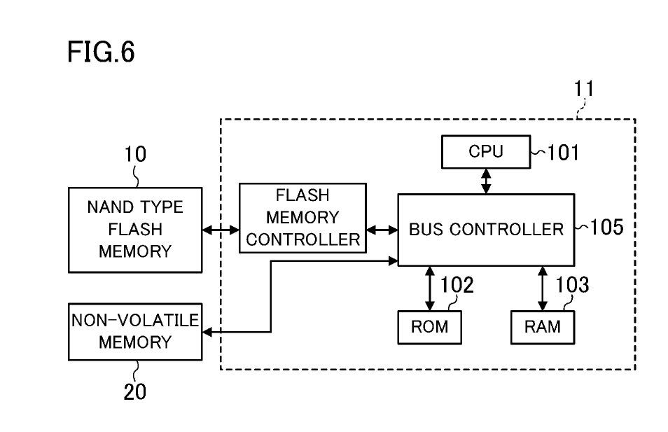

FIG. 6 illustrates an example configuration of a semiconductor device of a second embodiment. The semiconductor device has the configuration of the semiconductor device illustrated in FIG. 1, and in addition, a non-volatile memory 20. Note that the non-volatile memory 20 may be provided inside the system LSI 11 or may be provided outside the system LSI.

In the course of using the NAND type flash memory 10, the number of unreadable blocks in the NAND type flash memory 10 randomly increases. Thus, when access to the NAND type flash memory 10 is performed without the unreadable blocks being avoided, the start-up time of the semiconductor device may increase as the number of unreadable blocks increases. The semiconductor device illustrated in FIG. 6 performs the process of storing boot history information (information indicating from which blocks the divided programs D1, D2, D3 have been able to be normally read) in the non-volatile memory 20, and the process of sequentially reading the boot program from the NAND type flash memory 10 on a block-by-block basis while avoiding access to the unreadable blocks based on the boot history information.

[Boot History Information]

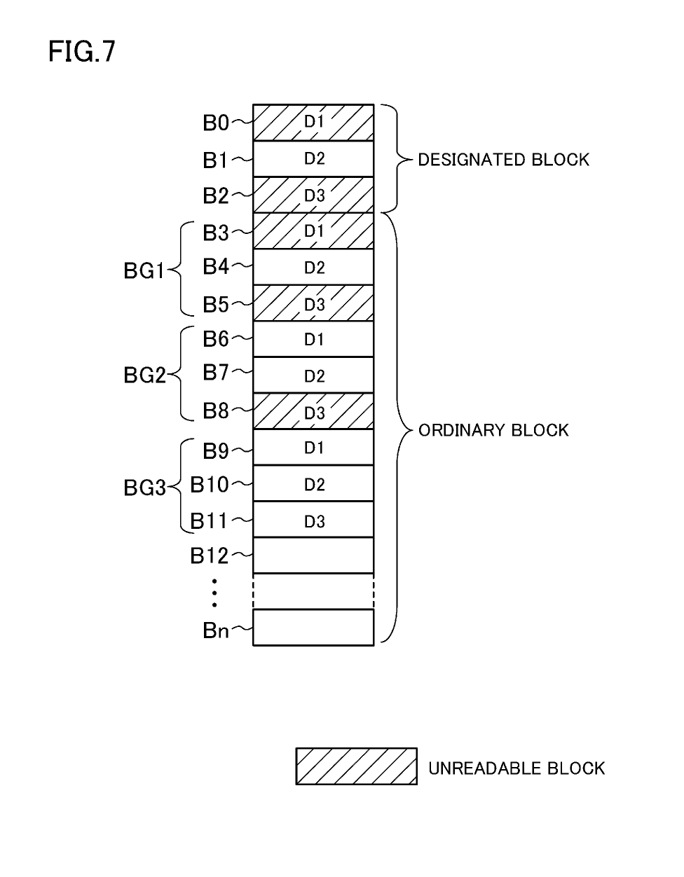

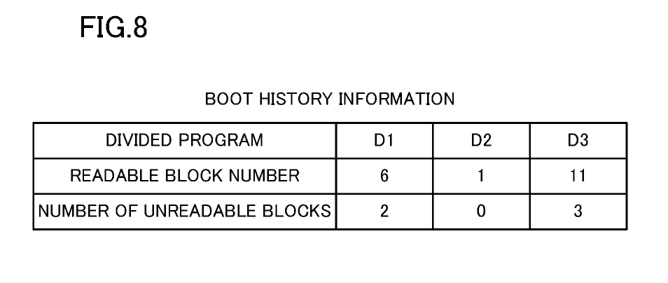

In the boot history information, the block numbers of blocks from which the divided programs D1, D2, D3 have been able to be normally read may be indicated. For example, as illustrated in FIG. 7, when the designated blocks B0, B2, and the ordinary blocks B3, B5, B8 are unreadable blocks, the divided programs D1, D2, D3 can be normally read from the ordinary block B6, the designated block B1, and the ordinary block B11, respectively. Thus, as illustrated in FIG. 8, in the boot history information, the block numbers (6, 1, 11) of the ordinary block B6, the designated block B1, and the ordinary block B11 are assigned to the divided programs D1, D2, D3, respectively.

Alternatively, in the boot history information, the number of unreadable blocks of each of the divided programs D1, D2, D3 (the number of blocks from which each of the divided programs cannot be normally read) may be indicated. Moreover, based on the number of unreadable blocks of each of the divided programs D1, D2, D3, the CPU 101 can detect blocks from which the divided programs D1, D2, D3 have been able to be normally read. For example, as illustrated in FIG. 7, when the designated blocks B0, B2, and the ordinary blocks B3, B5, B8 are unreadable blocks, the numbers of unreadable blocks (2, 0, 3) are assigned to the divided programs D1, D2, D3, respectively. In this case, the CPU 101 refers to the number of unreadable blocks, “2,” of the divided program D1, and can recognize that among the designated block B0 and the ordinary blocks B3, B6, B9 each of which stores the divided program D1, the designated block B0 on which the read process is firstly performed and the ordinary block B3 on which the read process is secondly performed are unreadable blocks, and that the divided program D1 can be normally read from the ordinary block B6 on which the read process is thirdly performed.

[Operation]

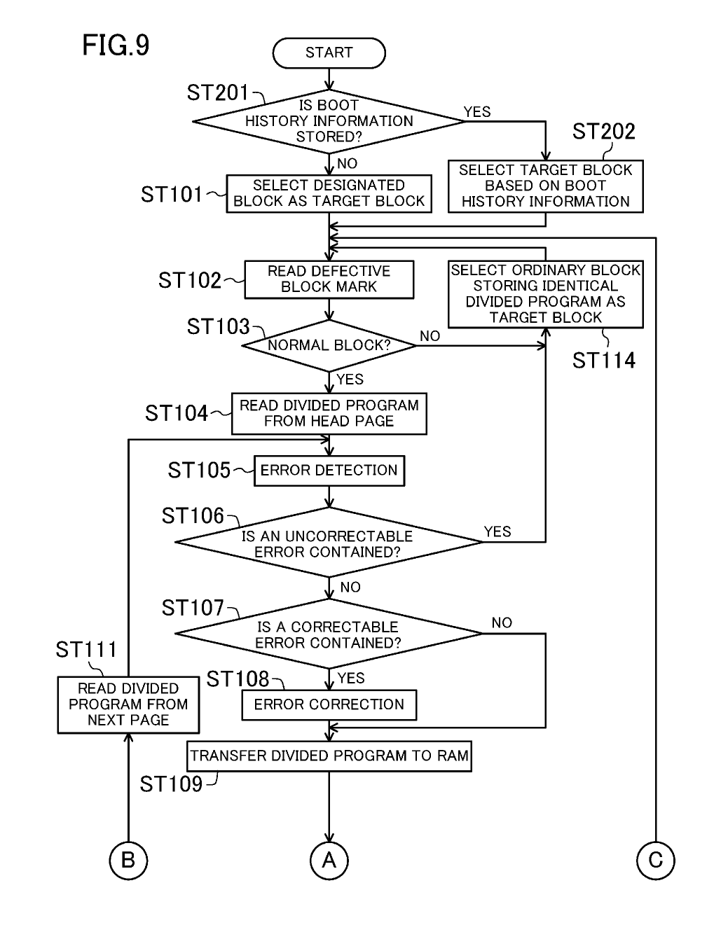

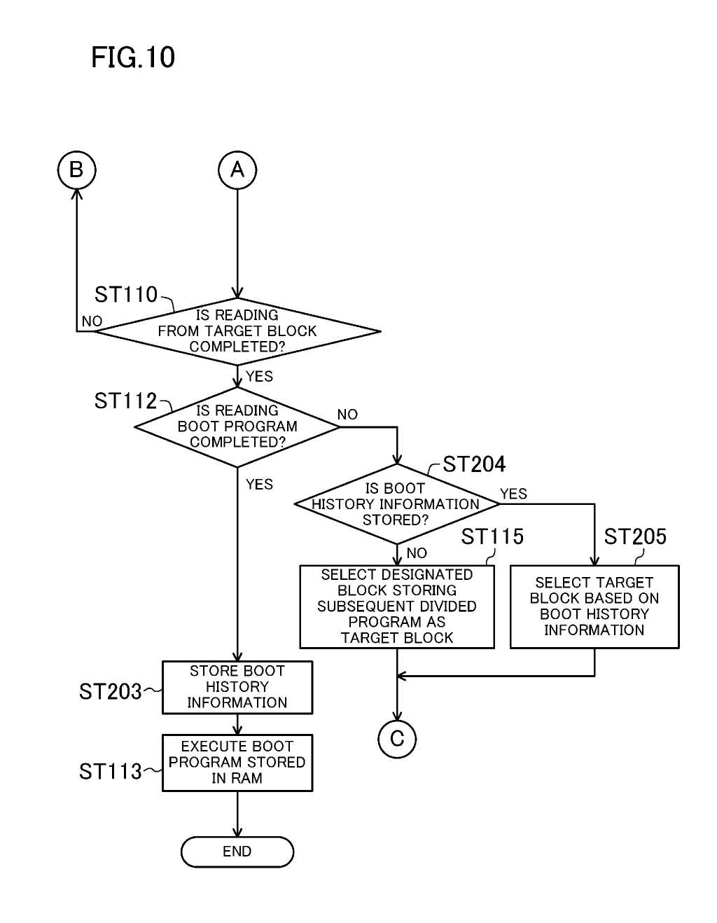

Next, with reference to FIGS. 9 and 10, a start-up process of the semiconductor device illustrated in FIG. 6 will be described. After a reset of the system LSI 11 is canceled, the CPU 101 executes the following operation according to the start-up program stored in the ROM 102. Here, in addition to steps ST101-ST115 illustrated in FIG. 4, the following steps ST201-ST205 are performed.

<<Step ST201>>

First, the CPU 101 accesses the non-volatile memory 20, and determines whether or not the boot history information has been stored in the non-volatile memory 20. If the boot history information has been stored in the non-volatile memory 20, the process proceeds to step ST202. If the boot history information has not been stored in the non-volatile memory 20, the process proceeds to step ST101.

<<Step ST202>>

Next, the CPU 101 reads the boot history information stored in the non-volatile memory 20. Among the designated block B0 and the ordinary blocks B3, B6, B9 each of which stores the first divided program D1, the CPU 101 selects a block indicated in the boot history information as a target block. For example, when the boot history information as illustrated in FIG. 8 is read, the CPU 101 does not select the designated block B0, but selects the ordinary block B6 as the target block. Next, the process proceeds to step ST102.

As described above, when the boot history information has been stored in the non-volatile memory 20, access of the CPU 101 starts from the block indicated in the boot history information, and when the boot history information has not been stored in the non-volatile memory 20, the access of the CPU 101 starts from the designated block.

<<Step ST203>>

If it is determined in step ST112 that reading the boot program has been completed, the CPU 101 creates boot history information based on the determination results in steps ST103, ST106, and stores the boot history information in the non-volatile memory 20. The boot history information indicates from which blocks the divided programs D1, D2, D3 have been able to be normally read in the current start-up process. The process proceeds to step ST113. For example, if it is determined in any one of steps ST103, ST106 that the divided program is not normally readable from the target block, the CPU 101 determines that the target block is an “unreadable block,” and if it is not determined in both steps ST103, ST106 that the divided program is not normally readable from the target block, the CPU 101 determines that the target block is a “readable block (block from which the divided program has been able to be normally read).” Based on the determination results, the CPU 101 creates the boot history information.

<<Step ST204>>

By contrast, if it is determined in step ST112 that the reading the boot program has not been completed, the CPU 101 accesses the non-volatile memory 20, and determines whether or not the boot history information has been stored in the non-volatile memory 20. If the boot history information has been stored in the non-volatile memory 20, the process proceeds to step ST205. If the boot history information has not been stored in the non-volatile memory 20, the process proceeds to step ST115.

<<Step ST205>>

Next, the CPU 101 reads the boot history information stored in the non-volatile memory 20. Among the designated block and the ordinary blocks which store subsequent divided programs, the CPU 101 selects a block indicated in the boot history information as a next target block. Next, the process proceeds to step ST102.

As described above, if the boot history information has been stored in the non-volatile memory 20, the CPU 101 selects the block indicated in the boot history information as a next target block, and if the boot history information has not been stored in the non-volatile memory 20, the CPU 101 selects a designated block storing the subsequent divided program as a next target block.

As described above, when the NAND type flash memory is accessed based on the boot history information, access to unreadable blocks can be avoided, so that it is possible to reduce the increase in the start-up time of the semiconductor device which occurs as the number of unreadable blocks increases.

### Third Embodiment

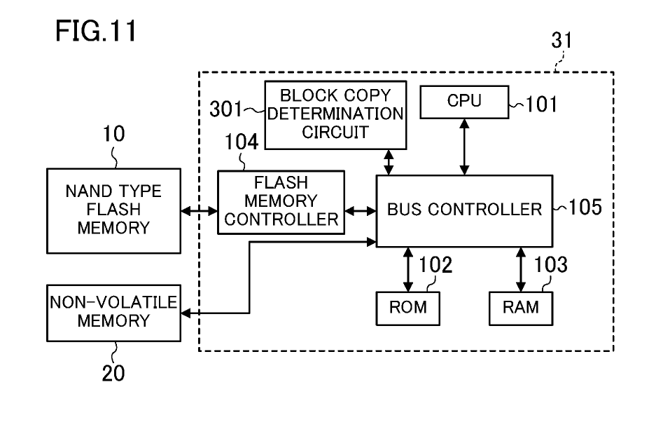

FIG. 11 illustrates an example configuration of a semiconductor device of a third embodiment. The semiconductor device includes a system LSI 31 instead of the system LSI 11 illustrated in FIG. 6. The system LSI 31 has the configuration of the system LSI 11 illustrated in FIG. 1, and in addition, a block copy determination circuit 301. For example, the block copy determination circuit 301 compares the number of unreadable blocks of each of the divided programs D1, D2, D3 with a preset threshold value, and outputs a copy request signal (signal to request that each of the divided programs D1, D2, D3 is copied to an unused block).

For example, in the NAND type flash memory 10, as illustrated in FIG. 7, when three of four blocks (the designated block B2 and the ordinary blocks B5, B8, B11) each storing the divided program D3 are unreadable blocks, the divided program D3 cannot be normally read if the ordinary block B11 becomes an unreadable block, so that the boot program cannot be accurately reconstructed. As a result, the semiconductor device cannot be activated. In the semiconductor device illustrated in FIG. 11, the process of copying the divided programs D1, D2, D3 to the unused blocks of the NAND type flash memory 10 (copying process) is performed based on the number of unreadable blocks of each of the divided programs D1, D2, D3.

[Operation]

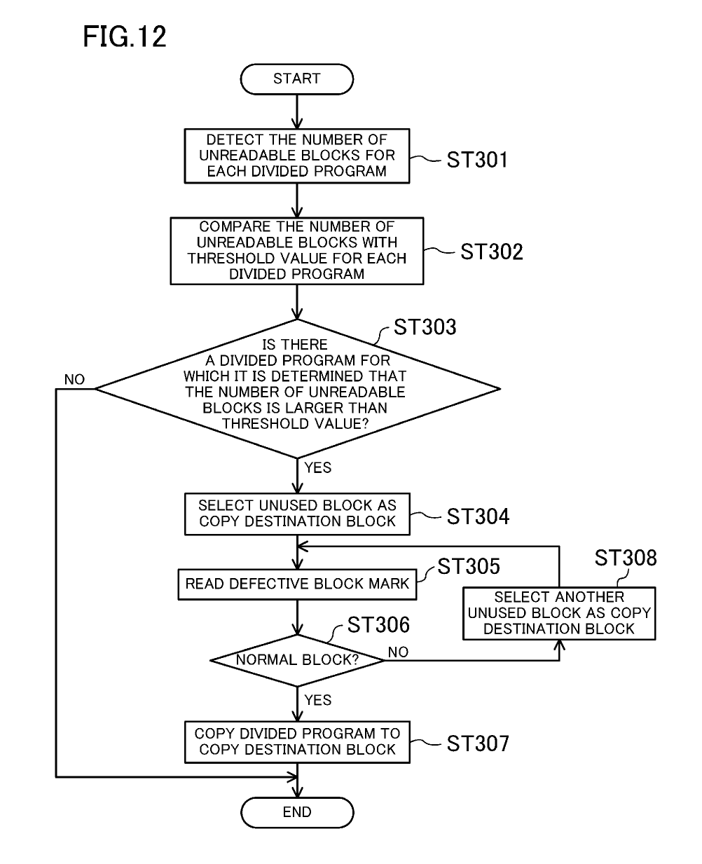

Next, with reference to FIG. 12, the copying process in the semiconductor device illustrated in FIG. 11 will be described.

<<Step ST301>>

The CPU 101 detects the number of unreadable blocks of each of the divided programs D1, D2, D3. For example, when the number of unreadable blocks of each of the divided programs D1, D2, D3 is indicated in the boot history information, the CPU 101 accesses the non-volatile memory 20, reads the boot history information stored in the non-volatile memory 20, and detects, from the boot history information, the number of unreadable blocks of each of the divided programs D1, D2, D3. Note that the CPU 101 may execute the start-up process (ST101-ST115) of the semiconductor device illustrated in FIG. 4 to detect the number of unreadable blocks of each of the divided programs D1, D2, D3.

<<Step ST302>>

Next, the block copy determination circuit 301 compares the number of unreadable blocks of each of the divided programs D1, D2, D3 with a preset threshold value. The block copy determination circuit 301 determines, for each divided program, whether or not the number of unreadable blocks is larger than the threshold value.

<<Step ST303>>

Next, the block copy determination circuit 301 determines whether or not among the divided programs D1, D2, D3, there is a divided program for which the number of unreadable blocks is determined to be larger than the threshold value. If there is such a divided program, the process proceeds to step ST304. If there is not such a divided program, the copying process ends.

<<Step ST304>>

Next, the block copy determination circuit 301 outputs the copy request signal to the CPU 101. In response to the copy request signal, the CPU 101 specifies the block number of an unused block included in the NAND type flash memory 10 and the page number “0” of the first page P0 included in the unused block. In this way, an unused block is selected as a copy destination block.

<<Step ST305>>

Next, based on the block number and the page number specified by the CPU 101, the flash memory controller 104 reads the defective block mark from the redundant area of the first page P0 included in the copy destination block.

<<Step ST306>>

Next, based on the value of the defective block mark read by the flash memory controller 104, the CPU 101 determines whether the copy destination block is a normal block or a defective block. If the copy destination block is a normal block, the process proceeds to step ST307. If the copy destination block is a defective block, the process proceeds to step ST308.

<<Step ST307>>

Next, in response to control by the CPU 101, the flash memory controller 104 reads a divided program stored in a readable block (block from which the divided program has been able to be normally read), and copies the read divided program to the copy destination block. For example, from a readable block storing a divided program for which it is determined in step ST303 that the number of unreadable blocks is larger than the threshold value, the flash memory controller 104 may read the divided program, and may copy the divided program to the copy destination block.

<<Step ST308>>

On the other hand, if it is determined in step ST306 that the copy destination block is a defective block, the CPU 101 selects another unused block (unused block different from the current copy destination block) included in the NAND type flash memory as a next copy destination block. Next, the process proceeds to step ST305.

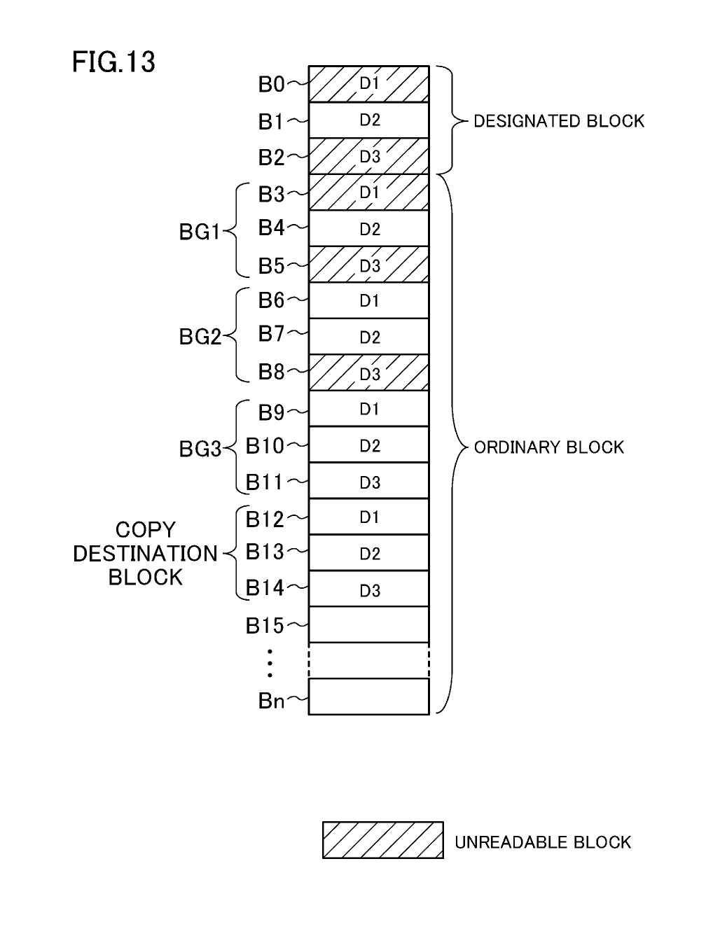

Note that all the divided programs D1, D2, D3 included in one boot program may be copied. In this case, the CPU 101 determines, after step ST307, whether or not one or more of the divided programs D1, D2, D3 remain without being copied. If one or more divided programs remain without being copied, steps ST304-ST308 are performed. If all the divided programs have been copied, the copying process ends. For example, as illustrated in FIG. 13, the CPU 101 may select three unused ordinary blocks B12, B13, B14 as three copy destination blocks, and the flash memory controller 104 may read the divided programs D1, D2, D3 from the ordinary block B6, the designated block B1, and the ordinary block B11, and copy the read divided programs D1, D2, D3 to the ordinary blocks B12, B13, B14, respectively.

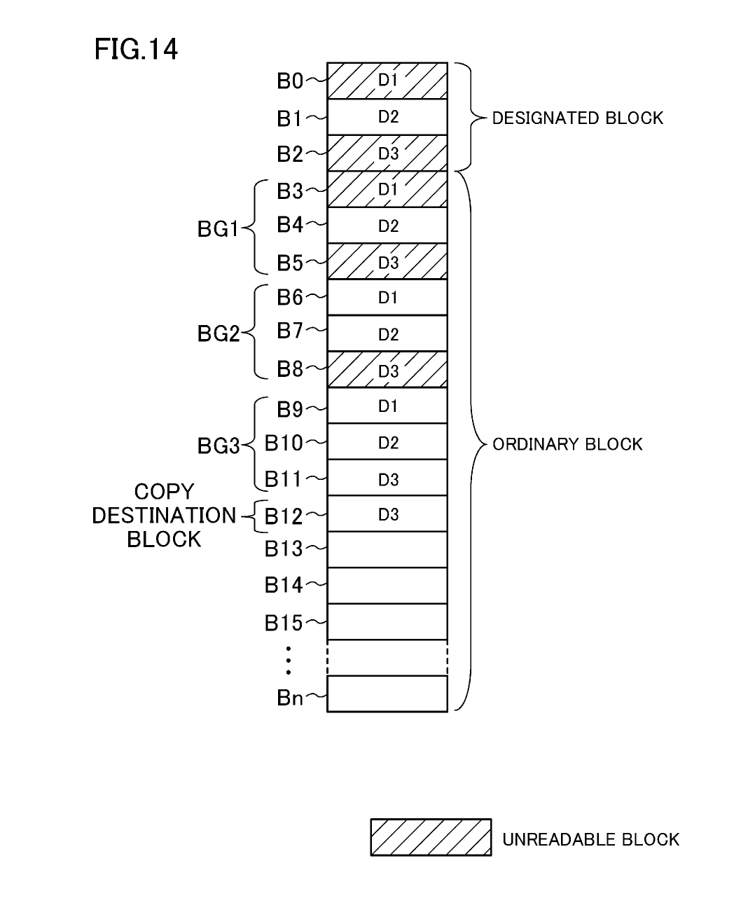

Alternatively, only a divided program for which it is determined that the number of unreadable blocks is larger than the threshold value may be copied. For example, as illustrated in FIG. 14, when the numbers of unreadable blocks for the divided programs D1, D2, D3 are 2, 0, 3, respectively, and the threshold value is “2,” the CPU 101 may select the unused ordinary block B12 as a copy destination block, and the flash memory controller 104 may read the divided program D3 from the ordinary block B11, and copy the read divided program D3 to the ordinary block B12.

As described above, when the copying process is performed based on the number of unreadable blocks of each of the divided programs D1, D2, D3, it is possible to avoid the situation in which the boot program cannot be accurately reconstructed and the semiconductor device cannot be activated.

Note that in the above embodiments, the number of designated blocks, the number of ordinary block groups, the number of ordinary blocks included in the ordinary block group, and the division number of the boot program are not limited to those described as the examples. Although a start-up process of the semiconductor device has been described as an example, the NAND type flash memory 10 may be configured to store data strings other than the boot program. That is, the NAND type flash memory 10 may include p designated blocks (p≧2) and two or more ordinary block groups, and each of the two or more ordinary block groups may include p ordinary blocks. Moreover, p divided data strings obtained by dividing the data string into p strings may be stored in the p designated blocks, respectively, and the p divided data strings stored in the p designated blocks may be copied to p ordinary blocks included in each of the two or more ordinary block groups.

As described above, the data processing method and the semiconductor integrated circuit have a high degree of data read reliability, and thus are useful for, for example, semiconductor devices in which a boot program is read form the NAND type flash memory, and which is activated based on the boot program.

Note that the above embodiments are substantially preferable examples, and are not intended to limit the scope of the present invention, objects to which the present invention is applied, or the application of the present invention.

What is claimed is:

1. A data processing method for sequentially processing a data string stored in a flash memory on a block-by-block basis, wherein
the flash memory includes p designated blocks, where p≧2, and ordinary block groups,
each of the ordinary block groups includes p ordinary blocks,
p divided data strings obtained by dividing the data string into p strings are stored in the p designated blocks, respectively,
the p divided data strings stored in the p designated blocks are respectively copied to the p ordinary blocks included in each of the ordinary block groups, and
reliability of the designated blocks is higher than reliability of the ordinary blocks,
the data processing method comprising:
(a) executing a read process on an ith designated block storing an ith divided data string, where 1≦i≦n;
(b) sequentially executing the read process on ith ordinary blocks each of which stores the ith divided data string and which are respectively included in the ordinary block groups if the ith divided data string is not normally read in the step (a);
(c) determining whether or not reading the p divided data strings has been completed if the ith divided data string is normally read in any one of the step (a) or (b); and
(d) executing the read process on an (i+1)th designated block storing an (i+1)th divided data string following the ith divided data string if it is determined in the step (c) that the reading the p divided data strings has not been completed.

2. The data processing method of claim 1, wherein each of the p designated blocks and the p ordinary blocks included in each of the ordinary block groups stores a defective block mark to determine whether the block is a defective block or a normal block, and
the read process includes
(e1) reading the defective block mark stored in a target block on which the read process is performed, and determining, based on the defective block mark, whether the target block is a defective block or a normal block,
(e2) determining that the divided data string is not normally readable from the target block if it is determined in the step (e1) that the target block is a defective block, and
(e3) reading the divided data string stored in the target block if it is determined in the step (e1) that the target block is a normal block.

3. The data processing method of claim 2, wherein
each of the p designated blocks and the p ordinary blocks included in each of the ordinary block groups stores an error correcting code used to detect and correct an error in the divided data string stored therein,
in the step (e3), the divided data string stored in the target block is read, and the error correcting code stored in the target block is read, and
the read process further includes
(e4) detecting and correcting an error in the divided data string read in the step (e3) based on the error correcting code read in the step (e3).

4. The data processing method of claim 1, further comprising:
(f) storing, in a non-volatile memory, history information indicating from which blocks the p divided data strings have been normally read if it is determined in the step (c) that the reading the p divided data strings has been completed.

5. The data processing method of claim 4, further comprising:
(g) determining whether or not the history information has been stored in the non-volatile memory;
(h) executing, based on the history information, the read process on any one of the ith designated block or the ith ordinary blocks each storing the ith divided data string if it is determined in the step (g) that the history information has been stored in the non-volatile memory;
(i) determining whether or not the history information is stored in the non-volatile memory if it is determined in the step (c) that the reading the p divided data strings has not been completed; and
(j) executing, based on the history information, the read process on any one of the (i+1)th designated block or (i+1)th ordinary blocks each storing the (i+1)th divided data string if it is determined in the step (i) that the history information has been stored in the non-volatile memory, wherein
the step (a) is performed when it is determined in the step (g) that the history information has not been stored in the non-volatile memory,
the step (b) is performed when the ith divided data string is not normally read in any one of the step (a) or (h),
the step (c) is performed when the ith divided data string is normally read in any one of the step (a), (b), or (h), and
the step (d) is performed when it is determined in the step (i) that the history information has not been stored in the non-volatile memory.

6. The data processing method of claim 1, further comprising:
(k) detecting, for each of the p divided data strings, among the designated block and the ordinary blocks each storing the divided data string, the number of blocks from which the divided data string is not normally read as the number of unreadable blocks;
(l) determining, for each of the divided data strings, whether or not the number of unreadable blocks detected in the step (k) is larger than a preset threshold value; and
(m) copying the divided data string, for which it is determined in the step (l) that the number of unreadable block is larger than the threshold value, to an unused block.

7. The data processing method of claim 1, wherein
the data string is a boot program to activate a CPU,
the data processing method further comprising:
(n) transferring the ith divided data string normally read in any one of the step (a) or (b) to a RAM, and
(o) allowing the CPU to execute the p divided data strings transferred to the RAM as the boot program if it is determined in the step (c) that the reading the p divided data strings has been completed.

8. A semiconductor integrated circuit for sequentially processing a data string stored in a flash memory on a block-by-block basis, the semiconductor integrated circuit comprising:
a CPU; and
a RAM, wherein
the flash memory includes p designated blocks, where p≧2, and ordinary block groups,
each of the ordinary block groups includes p ordinary blocks,
p divided data strings obtained by dividing the data string into p strings are stored in the p designated blocks, respectively,
the p divided data strings stored in the p designated blocks are copied to the p ordinary blocks included in each of the ordinary block groups, respectively,
reliability of the designated blocks is higher than reliability of the ordinary blocks,
the CPU executes a read process on an ith designated block storing an ith divided data string, where 1≦i≦n,
the CPU sequentially executes the read process on ith ordinary blocks each of which stores the ith divided data string and which are respectively included in the ordinary block groups if the ith divided data string is not normally read from the ith designated block,
the CPU transfers the ith divided data string normally read from any one of the ith designated block or the ith ordinary blocks to the RAM,
the CPU determines whether or not reading the p divided data strings has been completed if the ith divided data string is normally read from any one of the ith designated block or the ith ordinary blocks, and
the CPU executes the read process on an (i+1)th designated block storing an (i+1)th divided data string following the ith divided data string if the CPU determines that the reading the p divided data strings has not been completed.

9. The semiconductor integrated circuit of claim 8, wherein
the data string is a boot program, and
the CPU executes the p divided data strings transferred to the RAM as the boot program if the CPU determines that the reading the p divided data strings has been completed.

10. The semiconductor integrated circuit of claim 9, further comprising:
a non-volatile memory configured to store a start-up program which allows the CPU to sequentially process the data string stored in the flash memory on a block-by-block basis, wherein
the CPU operates based on the start-up program stored in the non-volatile memory.
